(19) United States
(12) Patent Application Publication
(10) Pub. No.: US 2026/0011673 A1
(43) Pub. Date: Jan. 8, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Yusuke KARASAWA, Nagano (JP)

(21) Appl. No.: 19/250,773

(22) Filed: Jun. 26, 2025

(30) Foreign Application Priority Data
Jul. 2, 2024 (JP) 2024-106998

(51) Int. Cl. H01L 23/00; H01L 23/13; H01L 23/31

(52) U.S. Cl. CPC H01L 24/20; H01L 23/13; H01L 23/3107; H01L 24/19; H01L 2224/19; H01L 2224/2105; H01L 2224/221

(57) ABSTRACT

An interconnect substrate includes a core layer, a first interconnect layer formed on a first surface of the core layer, a second interconnect layer formed on a second surface of the core layer, a cavity extending through the core layer, an electronic component in the cavity, a first insulating layer covering the electronic component and covering side surfaces, without covering an upper surface, of the first interconnect layer, and a second insulating layer covering the upper surface of the first interconnect layer and an upper surface of the first insulating layer, wherein the first insulating layer has a recess over the cavity recessed relative to the upper surface of the first insulating layer, a deepest part of the recess is located between a plane including the first surface and a plane including the upper surface of the first interconnect layer, and the second insulating layer fills the recess.

### CROSS-REFERENCE TO RELATED APPLICATIONS

The present application is based on and claims priority to Japanese Patent Application No. 2024-106998 filed on Jul. 2, 2024, with the Japanese Patent Office, the entire contents of which are incorporated herein by reference.

### FIELD

The disclosures herein relate to interconnect substrates and methods of making interconnect substrates.

### BACKGROUND

Interconnect substrates having openings for housing electronic components are known in the art. In an interconnect substrate of such a kind, for example, the space between an electronic component and the inner wall of the opening is filled with a filling resin composed of a resin different from the resin constituting the interlayer insulating layers. In such an interconnect substrate, a sufficient adhesion between the interlayer insulating layers and the filling resin is important.

There may be a need to improve adhesion between a first insulating layer covering an electronic component and a second insulating layer covering the upper surface of the first insulating layer in an interconnect substrate having the electronic component disposed in a cavity.
[Patent Document 1] Japanese Laid-Open Patent Publication No. 2019-67858

### SUMMARY

According to at least one embodiment, an interconnect substrate includes a core layer, a first interconnect layer formed on a first surface of the core layer, a second interconnect layer formed on a second surface of the core layer, a cavity extending through the core layer, an electronic component disposed in the cavity, a first insulating layer covering the electronic component in the cavity, extending from the cavity to the first surface of the core layer, and covering side surfaces, without covering an upper surface, of the first interconnect layer, and a second insulating layer covering the upper surface of the first interconnect layer and an upper surface of the first insulating layer, wherein the first insulating layer has a recess located over the cavity and recessed relative to the upper surface of the first insulating layer toward the electronic component, wherein a deepest part of the recess is located between a plane including the first surface of the core layer and a plane including the upper surface of the first interconnect layer, and wherein the second insulating layer fills the recess.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to an embodiment;

FIGS. 2A through 2D are drawings illustrating an example of a manufacturing process of the interconnect substrate according to the embodiment; and

FIGS. 3A through 3D are drawings illustrating the example of the manufacturing process of the interconnect substrate according to the embodiment.

### DESCRIPTION OF EMBODIMENTS

In the following, an embodiment of the invention will be described with reference to the accompanying drawings. In these drawings, the same constituent elements are referred to by the same reference numerals, and duplicate descriptions may be omitted.

### Structure of Interconnect Substrate

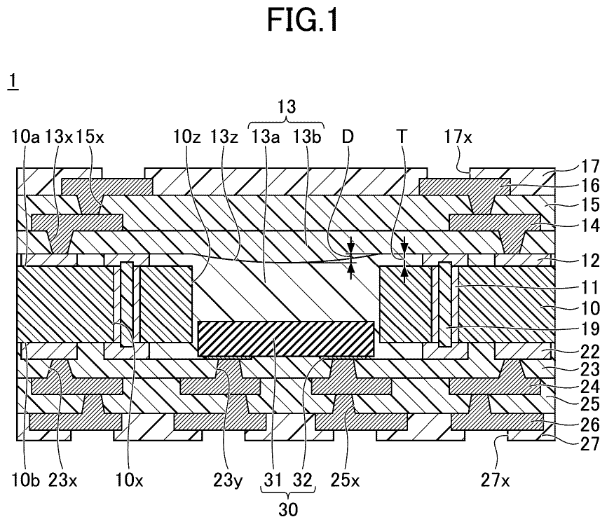

FIG. 1 is a cross-sectional view illustrating an example of an interconnect substrate according to a present embodiment. Referring to FIG. 1, an interconnect substrate 1 has interconnect layers and insulating layers laminated on either side of the core layer 10.

Specifically, the interconnect substrate 1 includes an interconnect layer 12, an insulating layer 13, an interconnect layer 14, an insulating layer 15, an interconnect layer 16, and a solder resist layer 17 successively laminated on a first surface 10a of the core layer 10. On a second surface 10b of the core layer 10, an interconnect layer 22, an insulating layer 23, an interconnect layer 24, an insulating layer 25, an interconnect layer 26, and a solder resist layer 27 are successively laminated. The number of interconnect layers and insulating layers laminated on the first surface 10a and the second surface 10b of the core layer 10 is not limited to the example illustrated in FIG. 1.

In the present embodiment, for convenience, the solder resist layer 17 side of the interconnect substrate 1 is referred to as the upper side or the first side, and the solder resist layer 27 side is referred to as the lower side or the second side. In addition, the surface of each part oriented toward the solder resist layer 17 is referred to as the first surface or the upper surface, and the surface of each part oriented toward the solder resist layer 27 is referred to as the second surface or the lower surface. It may be noted, however, that the interconnect substrate 1 may be placed upside down when used, or may be arranged at any angle. The plan view of an object refers to the view of the object as seen from the direction normal to the first surface 10a of the core layer 10, and the plan shape of an object refers to the shape of the object as seen from the direction normal to the first surface 10a of the core layer 10.

The core layer 10 may be, for example, a glass epoxy substrate made by impregnating glass cloth with an insulating resin such as an epoxy-based resin. The core layer 10 may alternately be, for example, a substrate made by impregnating a woven or nonwoven fabric of glass fiber, carbon fiber, aramid fiber, or the like with an epoxy-based resin or the like. The thickness of the core layer 10 is, for example, about 60 to 1600 μm. The core layer 10 has one or more through holes 10x extending through the core layer 10 in the thickness direction. The plan shape of each through hole 10x is, for example, circular.

A cavity 10z penetrating the core layer 10 and reaching the upper surface of the insulating layer 23 is formed in the core layer 10. An electronic component 30 is disposed in the cavity 10z. The electronic component 30 includes a body 31 and electrodes 32 formed on the electrode forming surface of the body 31. The electronic component 30 is disposed face-down in the cavity 10z with the electrodes 32 situated on the side with the interconnect layer 22. The lower surface of the electrodes 32 is flush with, for example, the lower surface of the interconnect layer 22. The vertical distance from the lower surface of the interconnect layer 22 to the upper surface of the body 31 is shorter than the vertical distance from the lower surface of the interconnect layer 22 to the first surface 10a of the core layer 10. The lower surface of the body 31 may be positioned closer to the interconnect layer 24 than is the second surface 10b of the core layer 10.

The electronic component 30 may be a passive component or an active component. The electronic component 30 may be, for example, an IPD (integrated passive device), a semiconductor chip, a capacitor, an inductor, a resistor, or the like. The plan shape of the cavity 10z is geometrically similar to the plan shape of the electronic component 30, for example, and the size thereof is larger than that of the electronic component 30. A plurality of electronic components 30 may be arranged in the cavity 10z.

The interconnect layer 12 is formed on the first surface 10a of the core layer 10. The interconnect layer 22 is formed on the second surface 10b of the core layer 10. The interconnect layer 12 and the interconnect layer 22 are electrically connected by one or more through interconnects 11 formed in the one or more through holes 10x. In the illustrated example, resin bodies 19 fill the center spaces of the through interconnects 11. Each resin body 19 has a cylindrical shape, for example, and its upper end extends into the interconnect layer 12 and its lower end extends into the interconnect layer 22. A through interconnect 11 may not have a resin body 19. In such a case, the entire through hole 10x is filled with the through interconnect 11.

The interconnect layers 12 and 22 are patterned in predetermined respective plan shapes. The interconnect layers 12 and 22 and the through interconnects 11 may be made of, for example, copper (Cu). The thickness of the interconnect layers 12 and 22 may be, for example, about 25 to 45 μm. It may be noted that the interconnect layer 12 may be thinner than the interconnect layer 22 by about several micrometers. The interconnect layer 12, the interconnect layer 22, and the through interconnects 11 may be seamlessly formed with each other.

The insulating layer 13 includes a first insulating layer 13a and a second insulating layer 13b. The first insulating layer 13a is an embedded insulating layer disposed in the cavity 10z. The first insulating layer 13a covers the electronic component 30 in the cavity 10z, and extends from the cavity 10z to the first surface 10a of the core layer 10 to cover the side surfaces, without covering the upper surface, of the interconnect layer 12. The first insulating layer 13a may extend from the cavity 10z to part of the second surface 10b of the core layer 10. It may be noted that, with respect to the electronic component 30, a part of the electrode forming surface of the body 31 may not be covered with the first insulating layer 13a, but may be covered with the insulating layer 23. In the electrode forming surface of the body 31, the region covered with the insulating layer 23 may be all regions located between adjacent electrodes 32, or a part of regions located between adjacent electrodes 32.

The first insulating layer 13a has a recess 13z located over the cavity 10z and recessed relative to the upper surface of the first insulating layer 13a toward the electronic component 30. At least a part of the recess 13z is located at a position overlapping the cavity 10z in plan view. For example, the outer perimeter of the recess 13z may not be located at a position overlapping the cavity 10z in plan view. The outer perimeter of the recess 13z may be outside the cavity 10z in plan view. The recess 13z has, for example, a bowl shape. Here, the term “bowl shape” refers to a shape with a depth that gradually increases from the perimeter to the center, and an inner wall surface that has a rounded profile.

The recess 13z is confined within the thickness T of the interconnect layer 12. That is, the deepest part of the recess 13z is located between a plane including the first surface 10a of the core layer 10 and a plane including the upper surface of the interconnect layer 12. The deepest part of the recess 13z does not reach a point closer to the electronic component 30 than is the plane including the first surface 10a of the core layer 10. The depth D of the recess 13z is, for example, 1 μm to 30 μm. That is, the distance between the plane including the upper surface of the interconnect layer 12 and the deepest part of the recess 13z is 1 μm to 30 μm.

The first insulating layer 13a located on the first surface 10a of the core layer 10 covers the side surfaces of the interconnect layer 12 without covering the upper surface thereof. The upper surface of the first insulating layer 13a is flush with, for example, the upper surface of the interconnect layer 12. The thickness of the first insulating layer 13a located on the first surface 10a of the core layer 10 is substantially the same as that of the interconnect layer 12.

The second insulating layer 13b covers the upper surface of the interconnect layer 12 and the upper surface of the first insulating layer 13a. The second insulating layer 13b fills the recesses 13z. The upper surface of the second insulating layer 13b is preferably flat. The thickness of the second insulating layer 13b located on the upper surface of the interconnect layer 12 may be, for example, about 30 to 40 μm.

The material of the second insulating layer 13b may be, for example, an insulating resin mainly composed of an epoxy-based resin or a polyimide-based resin. The second insulating layer 13b may contain a filler such as silica (SiO₂). The material of the first insulating layer 13a is preferably an insulating resin having higher fluidity than that of the second insulating layer 13b.

The second insulating layer 13b is provided with one or more via holes 13x penetrating the second insulating layer 13b and reaching the upper surface of the interconnect layer 12. Each via hole 13x may be an inverted truncated conical hole such that the diameter of the opening toward the insulating layer 15 is larger than the diameter of the opening at the upper surface of the interconnect layer 12.

The interconnect layer 14 is formed on the first side of the insulating layer 13. The interconnect layer 14 includes one or more via interconnects filling the one or more via holes 13x and an interconnect pattern formed on the upper surface of the insulating layer 13. The interconnect pattern is electrically connected to the interconnect layer 12 through the one or more via interconnects. The material and the thickness of the interconnect pattern of the interconnect layer 14 may be substantially the same as those of the interconnect layer 22, for example.

The insulating layer 15 is formed on the upper surface of the insulating layer 13 to cover the interconnect layer 14. The material and thickness of the insulating layer 15 may be substantially the same as those of the second insulating layer 13b, for example. The insulating layer 15 may contain a filler such as silica (SiO₂).

The insulating layer 15 is provided with one or more via holes 15x which penetrate the insulating layer 15 and reach the upper surface of the interconnect layer 14. Each via hole 15x may be an inverted truncated conical hole such that the diameter of the opening toward the solder resist layer 17 is larger than the diameter of the opening at the upper surface of the interconnect layer 14.

The interconnect layer 16 is formed on the first side of the insulating layer 15. The interconnect layer 16 includes one or more via interconnects filling the one or more via holes 15x and an interconnect pattern formed on the upper surface of the insulating layer 15. The interconnect pattern is electrically connected to the interconnect layer 14 through the one or more via interconnects. The material and the thickness of the interconnect pattern of the interconnect layer 16 may be, for example, substantially the same as those of the interconnect layer 22.

The solder resist layer 17 is a protective insulating layer provided as an outermost layer at the first side of the interconnect substrate 1, and is formed on the upper surface of the insulating layer 15 to cover the interconnect layer 16. The solder resist layer 17 may be formed of, for example, a photosensitive epoxy-based insulating resin or acrylic-based insulating resin. The thickness of the solder resist layer 17 is, for example, about 15 to 35 μm.

The solder resist layer 17 has one or more openings 17x. The one or more openings 17x penetrate the solder resist layer 17 and expose the upper surface of the interconnect layer 16. The interconnect layer 16 exposed within the one or more openings 17x may be used as pads for electrical connection with one or more electronic components such as semiconductor chips, for example.

On the surface of the interconnect layer 16 exposed within the one or more openings 17x, a metal layer may be formed, or an organic coating may be formed by an antioxidant treatment such as an OSP (organic solderability preservative) treatment. Examples of the metal layer include an Au layer, a Ni/Au layer (a metal layer made by laminating a Ni layer and an Au layer in this order), a Ni/Pd/Au layer (a metal layer made by laminating a Ni layer, a Pd layer, and an Au layer in this order), and a Sn layer.

The insulating layer 23 is formed on the second surface 10b of the core layer 10 to cover the interconnect layer 22. The insulating layer 23 covers the lower surface of the first insulating layer 13a extended to the second surface 10b of the core layer 10. The material and thickness of the insulating layer 23 may be substantially the same as those of the second insulating layer 13b, for example. The insulating layer 23 may contain a filler such as silica (SiO₂).

The insulating layer 23 is provided with one or more via holes 23x penetrating the insulating layer 23 and reaching the lower surface of the interconnect layer 22. The insulating layer 23 is further provided with via holes 23y which penetrate the insulating layer 23 and reach the lower surfaces of the electrodes 32 of the electronic component 30. The via holes 23x and 23y may each be a truncated conical hole such that the diameter of the opening toward the insulating layer 25 is larger than the diameter of the opening at the lower surface of the interconnect layer 22 or the lower surface of the electrodes 32.

The interconnect layer 24 is formed on the lower surface of the insulating layer 23. The interconnect layer 24 includes one or more via interconnects filling in the one or more via holes 23x, via interconnects filling the via holes 23y, and an interconnect pattern formed on the lower surface of the insulating layer 23. A part of the interconnect pattern is electrically connected to the interconnect layer 22 through the one or more via interconnects filling the one or more via holes 23x. Another part of the interconnect pattern is electrically connected to the electrodes 32 through the via interconnects filling the via holes 23y. The material and the thickness of the interconnect pattern of the interconnect layer 24 may be substantially the same as those of the interconnect layer 22, for example.

The insulating layer 25 is formed on the lower surface of the insulating layer 23 so as to cover the interconnect layer 24. The material and thickness of the insulating layer 25 may be substantially the same as those of the second insulating layer 13b, for example. The insulating layer 25 may contain a filler such as silica (SiO₂).

The insulating layer 25 is provided with via holes 25x which penetrate the insulating layer 25 and reach the lower surface of the interconnect layer 24. Each via holes 25x may be a truncated conical hole such that the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect pattern of the interconnect layer 26 may be substantially the same as those of the interconnect layer 22, for example.

The solder resist layer 27 is a protective insulating layer provided as an outermost layer at the second side of the interconnect substrate 1, and is formed on the lower surface of the insulating layer 25 so as to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed within the openings 27x may be used as pads for electrical connection to a mounting substrate such as a motherboard. According to need, the lower surface of the interconnect layer 26 exposed in the openings 27x may have a metal layer of the aforementioned kind formed thereon, or may be subjected to an oxidation prevention treatment such as OSP treatment.

As described heretofore, the interconnect substrate 1 is configured such that the first insulating layer 13a covering the electronic component 30 in the cavity 10z has the recess 13z recessed relative to the upper surface of the first insulating layer 13a toward the electronic component 30, and the second insulating layer 13b fills the recess 13z. The provision of the recess 13z, with the second insulating layer 13b filling the recess 13z, effectively increases the contact area between the first insulating layer 13a and the second insulating layer 13b, thereby improving the adhesion between the first insulating layer 13a and the second insulating layer 13b.

In the manufacturing process of the interconnect substrate 1, for example, gas contained in the first insulating layer 13a may try to escape toward the second insulating layer 13b. In this case, if the adhesion between the first insulating layer 13a and the second insulating layer 13b were weak, there would be concern that the second insulating layer 13b could swell due to the pressure of the gas. In contrast, the interconnect substrate 1 is configured such that the adhesion between the first insulating layer 13a and the second insulating layer 13b is sufficiently strong to suppress the occurrence of swelling.

In the interconnect substrate 1, the deepest part of the recess 13z is located between a plane including the first surface 10a of the core layer 10 and a plane including the upper surface of the interconnect layer 12. With this arrangement, recess 13z does not become excessively deep, which reduces the likelihood that the upper surface of the second insulating layer 13b will lose flatness by conforming to the shape of the recess 13z.

In the interconnect substrate 1, a part of the electrode forming surface of the electronic component 30 is covered with the insulating layer 23. This creates an anchoring effect, which effectively improves the adhesion between the insulating layer 23, the electronic component 30, and the first insulating layer 13a.

In the interconnect substrate 1, the upper surface of the interconnect layer 12 is not covered with the first insulating layer 13a and is covered with the second insulating layer 13b. As the second insulating layer 13b, a resin material excellent in electrical insulation and moisture resistance may be selected while disregarding the ability to fill the cavity 10z, thereby effectively improving the reliability of the interconnect substrate 1. For the first insulating layer 13a, the ability to fill the cavity 10z takes priority over the electrical insulation and moisture resistance.

### Method of Making Interconnect Substrate

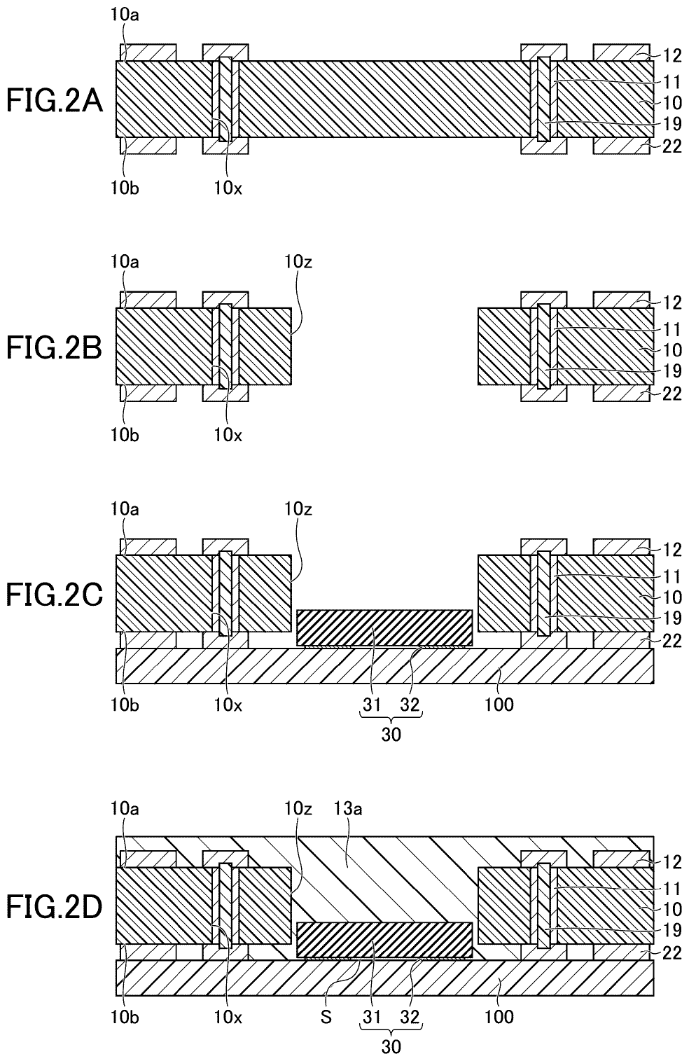

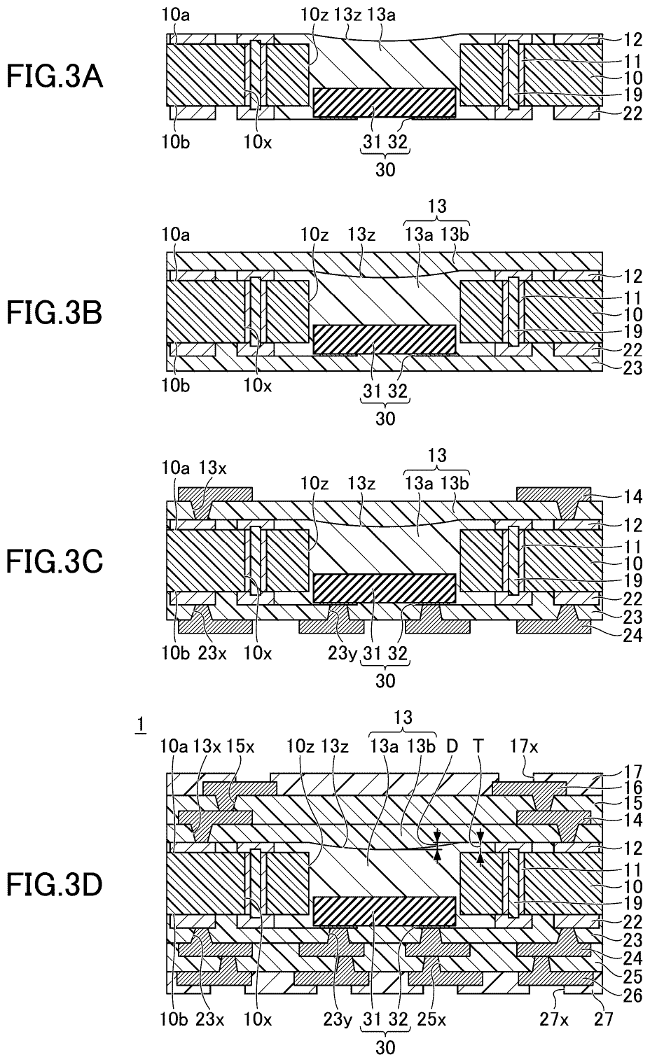

FIGS. 2A through 2D and FIGS. 3A through 3D are drawings illustrating an example of the manufacturing process of the interconnect substrate according to the present embodiment, and are cross-sectional views corresponding to FIG. 1. The following description is directed to an example of the process of manufacturing a single interconnect substrate. Alternatively, the manufacturing process may involve making a plurality of portions to become respective interconnect substrates and forming individual interconnect substrates by singulation.

In the step illustrated in FIG. 2A, the core layer 10 is prepared, with the interconnect layer 12 on the first surface 10a, the interconnect layer 22 on the second surface 10b, and the through interconnects 11 and the resin bodies 19 in the through holes 10x. To be more specific, a laminate of the core layer 10 such as a glass epoxy substrate and solid plain copper foils on both sides thereof is first prepared. Then, the through holes 10x are formed in the laminate to penetrate the core layer 10 and the copper foils on both surfaces by laser processing using a CO₂ laser or the like. Desmearing is performed as necessary to remove the resin residue of the core layer 10 adhered to the inner wall surfaces of the through holes 10x.

Next, a seed layer (copper or the like) covering the copper foil on each surface and the inner wall surfaces of the through holes 10x is formed by, for example, electroless plating or sputtering, followed by forming an electroplated layer (copper or the like) on the seed layer by an electroplating method using the seed layer as the power supply path. By doing so, through holes are formed as the inner spaces of tubular formations of the electroplated layer, and these through holes are filled with an epoxy resin or the like to form the resin bodies 19. In this manner, the through holes 10x are filled with the electroplated layer formed on the seed layer to form the through interconnects 11, and the resin bodies 19 are formed inside the through interconnects 11. Then, electroless plating and electroplating are performed to form metal layers made of copper or the like on the upper and lower ends of the through interconnects 11 and the resin bodies 19. The first surface 10a and the second surface 10b of the core layer 10 are covered with interconnect layers 12 and 22, respectively, which are each a laminate of the copper foil, the seed layer, the electroplated layer, and the metal layers. Thereafter, the interconnect layers 12 and 22 are patterned into predetermined plan shapes by a subtractive method or the like. It may be noted that at this point, the interconnect layer 12 has the same thickness as the interconnect layer 22.

In the step illustrated in FIG. 2B, the cavity 10z extending from the first surface 10a to the second surface 10b is formed in the core layer 10. The cavity 10z may be formed by laser machining or routing, for example. Desmearing is performed as necessary to remove resin residue of the core layer 10 adhering to the inner wall surface of the cavity 10z.

In the step illustrated in FIG. 2C, the electronic component 30 is disposed in the cavity 10z. To be more specific, a support film 100 is first laminated on the lower surface of the interconnect layer 22 so as to close the cavity 10z. The support film 100 may be, for example, a resin film with weak adhesion. Next, the electronic component 30 having the electrodes 32 is arranged face down on the upper surface of the support film 100 exposed in the cavity 10z. Arranging the electronic component 30 may involve, for example, using a component mounter.

In the step illustrated in FIG. 2D, the first insulating layer 13a is formed to cover the electronic component 30 in the cavity 10z and to extend from the cavity 10z to the first surface 10a of the core layer 10 to cover the upper and side surfaces of the interconnect layer 12. The first insulating layer 13a also extends from the cavity 10z to a part of the second surface 10b of the core layer 10. The first insulating layer 13a may be formed, for example, by applying an epoxy-based resin liquid or paste or the like so as to cover the electronic component 30 and to extend from the cavity 10z to the first surface 10a of the core layer 10, and then curing it. At this time, the viscosity, application amount, application duration, and the like of the insulating resin to become the first insulating layer 13a are adjusted so as to form at least one void S which is not filled with the first insulating layer 13a on a part of the electrode forming surface of the body 31 of the electronic component 30. The height of the void S, that is, the height of the electrodes 32, may be, for example, about 10 μm. After these processes, the support film 100 is detached.

In the step illustrated in FIG. 3A, the upper surface side of the first insulating layer 13a is polished to expose the upper surface of the interconnect layer 12 and to form the recess 13z, which is located over the cavity 10z and recessed relative to the upper surface of the first insulating layer 13a toward the electronic component 30. At this time, the polishing amount is adjusted so that the deepest portion of the recess 13z is located between a plane including the first surface 10a of the core layer 10 and a plane including the upper surface of the interconnect layer 12. That is, the deepest portion of the recess 13z is not located further toward the electronic component 30 than the first surface 10a of the core layer 10. A buffing machine may be used for polishing, for example. Since the upper surface of the interconnect layer 12 is also polished, the thickness of the interconnect layer 12 becomes smaller by several micrometers than the thickness of the interconnect layer 22. The roughness of the upper surface of the interconnect layer 12 is smaller than that of the lower surface of the interconnect layer 22. For example, the roughness Ra of the upper surface of the interconnect layer 12 is from 300 nm to 500 nm, and the roughness Ra of the lower surface of the interconnect layer 22 is from 400 nm to 600 nm.

In the step illustrated in FIG. 3B, the second insulating layer 13b covering the upper surface of the interconnect layer 12 and the upper surface of the first insulating layer 13a is formed. To be more specific, the second insulating layer 13b is formed by, for example, laminating an epoxy-based resin film or the like in a semi-cured state so as to cover the upper surface of the interconnect layer 12 and the upper surface of the first insulating layer 13a, and then curing it. The second insulating layer 13b fills the recess 13z. The second insulating layer 13b is preferably formed to have a flat upper surface. Further, the second surface 10b of the core layer 10 is laminated with an epoxy-based resin film or the like in a semi-cured state so as to cover the interconnect layer 22, and, then, the resin is cured to form the insulating layer 23. The insulating layer 23 is formed so as to cover the lower surfaces of the electrodes 32 of the electronic component 30 and to fill the void S. Instead of laminating epoxy-based resin films or the like, the second insulating layer 13b and the insulating layer 23 may be formed by applying and then curing an epoxy-based resin liquid or paste or the like.

In the step illustrated in FIG. 3C, the interconnect layers 14 and 24 are formed. To be more specific, the via holes 13x are first formed in the second insulating layer 13b to penetrate the second insulating layer 13b and expose the upper surface of the interconnect layer 12. The via holes 23x penetrating the insulating layer 23 and exposing the lower surface of the interconnect layer 22, and the via holes 23y penetrating the insulating layer 23 and exposing the lower surface of the electrodes 32 of the electronic component 30 are formed in the insulating layer 23. The via holes 13x, 23x, and 23y may be formed by a laser processing method using, for example, a CO2 laser. After the via holes 13x, 23x, and 23y are formed, desmearing is preferably performed to remove resin residues adhered to the surfaces of the interconnect layer 12, the interconnect layer 22, and the electrodes 32 which are exposed at the terminuses of the via holes 13x, 23x, and 23y, respectively.

Next, the interconnect layer 14 is formed on the first side of the insulating layer 13. The interconnect layer 14 includes via interconnects filling the via holes 13x and an interconnect pattern formed on the upper surface of the second insulating layer 13b. The interconnect layer 14 is electrically connected to the interconnect layer 12 situated at the bottom of the via holes 13x.

Further, the interconnect layer 24 is formed on the second side of the insulating layer 23. The interconnect layer 24 includes via interconnects filling the via holes 23x, via interconnects filling the via holes 23y, and an interconnect pattern formed on the lower surface of the insulating layer 23. A part of the interconnect pattern is electrically connected to the interconnect layer 22 via the via interconnects filling the via holes 23x. Another part of the interconnect pattern is electrically connected to the electrodes 32 via the via interconnects filling the via holes 23y.

The interconnect layers 14 and 24 may be formed by any interconnect formation method known in the art, such as the semi-additive method and the subtractive method. For example, when the semi-additive method is used to form the interconnect layer 14, a seed layer of copper is formed by electroless plating on the surface of the second insulating layer 13b including the inner walls of the via holes 13x and the surface of the interconnect layer 12 exposed within the via holes 13x. A plating resist pattern having openings corresponding to the shape of the interconnect pattern of the interconnect layer 14 is subsequently formed on the seed layer, and an electrolytic plating layer is deposited on the seed layer exposed through the openings of the plating resist pattern by electrolytic plating of copper using the seed layer as the power supply path. After the plating resist pattern is removed, etching is performed using the electrolytic plating layer as a mask to remove the seed layer not covered with the electrolytic plating layer. Through this process, the interconnect layer 14 having the via interconnect and the interconnect pattern is effectively fabricated. The interconnect layer 24 may also be formed by substantially the same method.

In the step illustrated in FIG. 3D, the insulating layer 15 is formed on the upper surface of the insulating layer 13 so as to cover the interconnect layer 14. Also, the insulating layer 25 is formed on the lower surface of the insulating layer 23 so as to cover the interconnect layer 24. The insulating layers 15 and 25 may be formed by substantially the same method as the second insulating layer 13b, for example. Thereafter, as in FIG. 3C, the interconnect layer 16 is formed on the first side of the insulating layer 15, and the interconnect layer 26 is formed on the second side of the insulating layer 25.

Subsequently, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed by applying, for example, a liquid or paste of photosensitive epoxy-based insulating resin or photosensitive acrylic-based insulating resin to the upper surface of the insulating layer 15 so as to cover the interconnect layer 16 by screen printing, roll coating, spin coating, or the like. Alternatively, a film of photosensitive epoxy-based insulating resin or photosensitive acrylic-based insulating resin may be laminated on the upper surface of the insulating layer 15 so as to cover the interconnect layer 16. The method of forming the solder resist layer 27 is substantially the same as that of the solder resist layer 17.

By exposing and developing the solder resist layers 17 and 27, the openings 17x exposing portions of the upper surface of the interconnect layer 16 are formed in the solder resist layer 17 (photolithography method), and the openings 27x exposing portions of the lower surface of the interconnect layer 26 are formed in the solder resist layer 27 (photolithography method). The plan shapes of the openings 17x and 27x may each be, for example, circular. The diameters of the openings 17x and 27x may be determined as appropriate according to the object (semiconductor chip, motherboard, etc.) to be connected.

In this step, the metal layers as previously described may be formed on the upper surface of the interconnect layer 16 exposed at the bottoms of the openings 17x and on the lower surface of the interconnect layer 26 exposed at the terminuses of the openings 27x by, for example, electroless plating. Alternatively, oxidation prevention treatment such as OSP treatment may be performed instead of forming the metal layers. By following these steps, the fabrication of the interconnect substrate 1 is completed.

According to at least one embodiment, in an interconnect substrate having electronic components arranged in a cavity, adhesion between the first insulating layer covering the electronic components and the second insulating layer covering the upper surface of the first insulating layer can be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exclusively include the subject matter set out in the following clause.

[Clause] A method of making an interconnect substrate, comprising: providing a core layer having a first interconnect layer on a first surface
and a second interconnect layer on a second surface;
forming a cavity penetrating the core layer;
disposing an electronic component in the cavity;
forming a first insulating layer that covers the electronic component in the cavity and that extends from the cavity to the first surface of the core layer to cover upper and side surfaces of the first interconnect layer;
polishing an upper surface of the first insulating layer to expose the upper surface of the first interconnect layer and to form a recess that is located over the cavity and that is recessed relative to the upper surface of the first insulating layer toward the electronic component; and
forming a second insulating layer covering the upper surface of the first interconnect layer and the upper surface of the first insulating layer,
wherein a deepest part of the recess is located between a plane including the first surface of the core layer and a plane including the upper surface of the first interconnect layer, and
wherein the second insulating layer fills the recess.

What is claimed is:

1. An interconnect substrate comprising:
a core layer;
a first interconnect layer formed on a first surface of the core layer;
a second interconnect layer formed on a second surface of the core layer;
a cavity extending through the core layer;
an electronic component disposed in the cavity;
a first insulating layer covering the electronic component in the cavity, extending from the cavity to the first surface of the core layer, and covering side surfaces, without covering an upper surface, of the first interconnect layer; and
a second insulating layer covering the upper surface of the first interconnect layer and an upper surface of the first insulating layer,
wherein the first insulating layer has a recess located over the cavity and recessed relative to the upper surface of the first insulating layer toward the electronic component,
wherein a deepest part of the recess is located between a plane including the first surface of the core layer and a plane including the upper surface of the first interconnect layer, and
wherein the second insulating layer fills the recess.

2. The interconnect substrate according to claim 1, wherein the first interconnect layer is thinner than the second interconnect layer.

3. The interconnect substrate according to claim 2, wherein the upper surface of the first interconnect layer has a roughness smaller than a lower surface of the second interconnect layer.

4. The interconnect substrate according to claim 2, wherein the upper surface of the first interconnect layer is flush with the upper surface of the first insulating layer.

5. The interconnect substrate according to claim 1, further comprising a third insulating layer formed on the second surface of the core layer and covering the second interconnect layer,
wherein the electronic component has an electrode forming surface on which an electrode is formed, and is disposed in the cavity with the electrode situated on a side with the second interconnect layer, and
wherein a part of the electrode forming surface is covered with the third insulating layer.

6. The interconnect substrate according to claim 1, wherein a distance between the plane including the upper surface of the first interconnect layer and the deepest part of the recess is from 1 μm to 30 μm.
